(19) United States
(12) Patent Application Publication
(10) Pub. No.: US 2020/0035768 A1
(43) Pub. Date: Jan. 30, 2020

(54) DISPLAY DEVICE, DISPLAY DEVICE PRODUCTION METHOD, DISPLAY DEVICE PRODUCTION APPARATUS, DEPOSITION APPARATUS, AND CONTROLLER

(71) Applicant: Sharp Kabushiki Kaisha, Sakai City, Osaka (JP)

(72) Inventors: Tohru OKABE, Sakai City (JP); Hiroki TANIYAMA, Sakai City (JP); Ryosuke GUNJI, Sakai City (JP); Shinsuke SAIDA, Sakai City (JP); Hiroharu JINMURA, Yonago-shi (JP); Yoshihiro NAKADA, Yonago-shi (JP); Akira INOUE, Yonago-shi (JP)

(21) Appl. No.: 16/497,638

(22) PCT Filed: Mar. 29, 2017
(86) PCT No.: PCT/JP2017/012888

§ 371 Date: Sep. 25, 2019

(51) Int. Cl. H01L 27/32; H01L 51/52; H01L 51/50

(52) U.S. Cl. CPC H01L 27/3246; H01L 51/5218; H01L 51/56; H01L 51/5012; H01L 2251/308; H01L 27/3218

(57) ABSTRACT

A display device including: a plurality of subpixels (SP) each including (i) a first electrode (22), (ii) a bank (23) covering an edge of the first electrode, (iii) an EL layer (24) provided in a layer higher than the first electrode, and (iv) a second electrode (25) provided in a layer higher than the EL layer, the bank having a first sloped part (23x) and a second sloped part (23y), the second sloped part having an inclination smaller than that of the first sloped part.

### TECHNICAL FIELD

The present invention relates to a display device.

### BACKGROUND ART

Patent Literature 1 discloses a subpixel structure which is included in an organic EL panel and which includes (i) banks covering edges of lower electrodes, (ii) organic layers (including a light emission layer) provided in the banks, and (iii) an lower electrode covering the organic layer.

### CITATION LIST

### Patent Literature

[Patent Literature 1]

Japanese Patent Application Publication Tokukai No. 2016-18849 (Publication date: Feb. 1, 2016)

### SUMMARY OF INVENTION

### Technical Problem

The subpixel structure disclosed in Patent Literature 1 poses a risk of, for example, the upper electrode (which serves as a common electrode) encountering step-caused disconnection at a sloped part.

### Solution to Problem

A display device in accordance with an aspect of the present invention includes: a plurality of subpixels: each of the plurality of subpixels including: a first electrode; a bank provided so as to cover an edge of the first electrode; an EL layer provided in a layer higher than the first electrode; and a second electrode provided in a layer higher than the EL layer, the bank having a first sloped part and a second sloped part whose inclination is smaller than that of the first sloped part.

### Advantageous Effects of Invention

With an aspect of the present invention, it is possible to increase light extraction efficiency at subpixels while conductivity of a second electrode is guaranteed.

### BRIEF DESCRIPTION OF DRAWINGS

FIG. 1 is a flowchart showing an example of a method of producing a display device.

FIG. 2 is a cross-sectional view showing an example of a configuration of a display device in accordance with the present embodiment.

FIG. 3 is a flowchart showing an example of steps involved in forming a light-emitting element layer.

FIG. 4 is a set of views (a) and (b) which are a cross-sectional view and a plan view, respectively, showing an example of a subpixel structure in accordance with Embodiment 1.

FIG. 5 is a view schematically showing an example of steps involved in formation of a bank in accordance with Embodiment 1.

FIG. 6 is a view schematically showing a variation of steps involved in formation of the bank in accordance with Embodiment 1.

FIG. 7 is a plan view showing an example of a variation of the bank in accordance with Embodiment 1.

FIG. 8 is a plan view showing an example of an arrangement of a plurality of banks in accordance with Embodiment 1.

FIG. 9 is a plan view showing an example of another arrangement of a plurality of banks in accordance with Embodiment 1.

FIG. 10 is a plan view showing an example of yet another arrangement of a plurality of banks in accordance with Embodiment 1.

FIG. 11 is a block diagram showing an example of a configuration of the display device production apparatus in accordance with Embodiment 1.

FIG. 12 is a set of views (a) and (b) which are a plan view and a cross-sectional view, respectively, showing an example of a configuration of a bank in accordance with Embodiment 2.

FIG. 13 is a plan view showing an example of an arrangement of a plurality of banks in accordance with Embodiment 2.

FIG. 14 is a plan view showing examples of (i) a configuration of a bank in accordance with Embodiment 3 and (ii) an arrangement of a plurality of banks in accordance with Embodiment 3.

### DESCRIPTION OF EMBODIMENTS

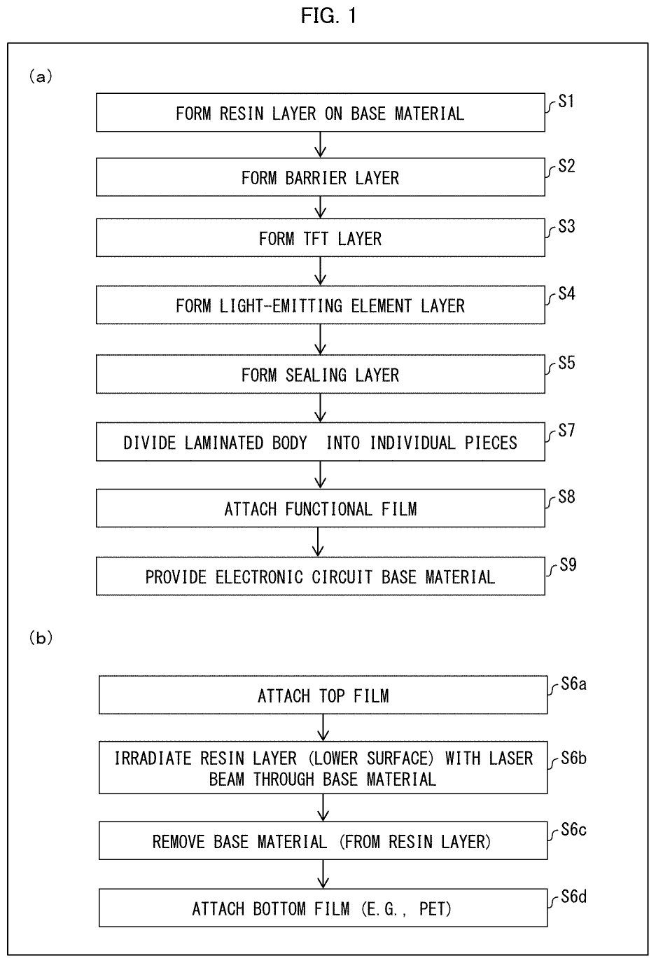

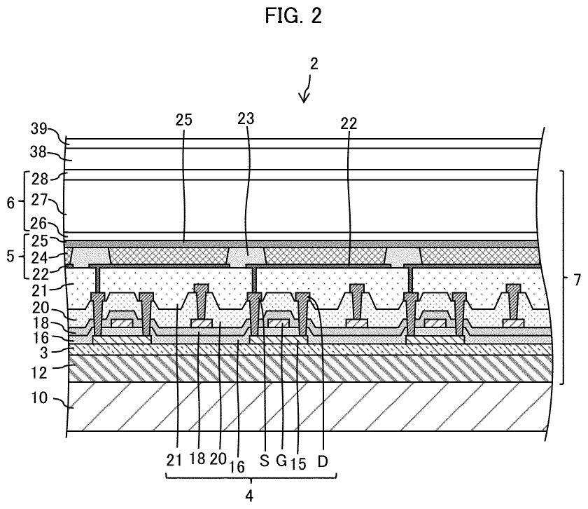

FIG. 1 is a flowchart showing an example of a method of producing a display device. FIG. 2 is a cross-sectional view showing an example of a configuration of a display device in accordance with the present embodiment.

As illustrated in (a) of FIG. 1 and in FIG. 2, a resin layer 12 is first formed on a base material 10 (Step S1). Next, a barrier layer 3 is formed (Step S2). Next, a TFT layer 4, which includes inorganic insulating films 16, 18, and 20 and an interlayer insulating film 21, is formed (Step S3). Next, a light-emitting element layer (such as an OLED element layer) 5 is formed (Step S4). Next, a sealing layer 6, which includes inorganic sealing films 26 and 28 and an organic sealing film 27, is formed, so that a laminated body 7 is formed (Step S5). Next, the laminated body 7 together with the base material 10 is divided into individual pieces (Step S7). Next, functional films 39 are attached to respective pieces via adhesive layers 38 (Step S8). Next, at respective end parts of the TFT layers 4, electronic circuit boards are provided (Step S9). This causes a display device 2 illustrated in FIG. 2 to be obtained. Note that each of the steps above is carried out by a production apparatus for producing the display device.

In a case where a flexible display device is to be produced, as illustrated in (b) of FIG. 1 and in FIG. 2, the laminated body 7 is provided on a glass substrate, and then a top film is attached onto the laminated body 7 via the adhesive layer (Step S6a). Next, a lower surface of the resin layer 12 is irradiated with a laser beam through the glass substrate (Step S6b). In this step, the lower surface of the resin layer 12 (i.e., an interface with the glass substrate 10) changes in quality due to abrasion. This causes a binding force between the resin layer 12 and the glass base material to be reduced. Next, the glass substrate is removed from the resin layer 12 (Step S6c). Next, the base material 10 (such as a bottom film made of, for example, PET) is attached to the lower surface of the resin layer 12 via the adhesive layer (Step S6d). Subsequently, the process proceeds to Step S7.

The resin layer 12 is made of a material, examples of which encompass polyimide, epoxy, and polyamide. The bottom film 10 is made of a material, examples of which encompass polyethylene terephthalate (PET).

The barrier layer 3 is a layer for preventing moisture and impurities from reaching the TFT layers 4 or the light-emitting element layer 5 while the display device is being used. The barrier layer 3 can be configured by, for example, (i) a silicon oxide film formed by CVD, (ii) a silicon nitride film formed by CVD, (iii) a silicon oxynitride film formed by CVD, or (iv) a laminated film made up of these films. The inorganic barrier layer 3 has a thickness of, for example, 50 nm to 1500 nm.

The TFT layers 4 each include (i) a semiconductor film 15, (ii) the inorganic insulating film 16 (gate insulating film) provided on an upper side of the semiconductor film 15, (iii) gate electrodes G provided on an upper side of the gate insulating film 16, (iv) the inorganic insulating films 18 and 20 provided on upper sides of the gate electrodes G, (v) source electrodes S, drain electrodes D, and terminals TM which are provided on an upper side of the inorganic insulating film 20, and (vi) the interlayer insulating film 21 provided on respective upper sides of the source electrodes S and of the drain electrodes D. The semiconductor film 15, the inorganic insulating film 16, the gate electrodes G, the inorganic insulating films 18 and 20, the source electrodes S, and the drain electrodes D together constitute thin film transistors (TFT). In a non-active region of the TFT layer 4, a plurality of terminals are provided so as to be used for connecting the TFT layer 4 to an IC chip and to an electronic circuit board such as an FPC.

The semiconductor film 15 is made of, for example, low-temperature polysilicon (LTPS) or oxide semiconductor. The gate insulating film 16 can be configured by, for example, (i) a silicon oxide (SiOx) film formed by a CVD method, (ii) a silicon nitride (SiNx) film formed by a CVD method, or (iii) a laminated film made up of the silicon oxide film and the silicon nitride film. The gate electrode G, the source electrode S, the drain electrode D, and the terminals are each constituted by, for example, a single-layer film made of a metal containing at least one of aluminum (Al), tungsten (W), molybdenum (Mo), tantalum (Ta), chrome (Cr), titanium (Ti), and copper (Cu), or alternatively constituted by a laminated film of metals including at least one of these metals. Note that FIG. 2 shows that the TFT, having the semiconductor film 15 as a channel, has a top-gate structure. Alternatively, the TFT can have a bottom-gate structure (for example, in a case where the channel of the TFT is an oxide semiconductor).

The inorganic insulating films 18 and 20 can each be configured by, for example, (i) a silicon oxide (SiOx) film formed by a CVD method, (ii) a silicon nitride (SiNx) film formed by a CVD method, or (iii) a laminated film made up of the silicon oxide film and the silicon nitride film. The interlayer insulating film 21 can be made of, for example, a photosensitive organic material, such as polyimide or acrylic, which can be used for coating.

The light-emitting element layer 5 (e.g., organic light-emitting diode layer) includes (i) first electrodes 22 (e.g., anode) provided on an upper side of the interlayer insulating film 21, (ii) banks 23 defining subpixels of an active region DA, (iii) EL (electroluminescence) layers 24 provided on upper sides of the first electrodes 22, and (iv) a second electrode 25 provided on upper sides of the EL layers 24. The first electrodes 22, the EL layers 24, and the second electrode 25 together form light-emitting elements (e.g., organic light-emitting diodes).

The banks 23 are made of a photosensitive organic material, such as polyimide, epoxy, or acrylic, which can be used for coating. The banks 23 can be formed by a photolithography method. Note that a protruding structure (droplet stopper) can be formed on the non-active region by a step identical to that carried out for forming the banks 23. The protruding structure defines edges of the organic sealing film 27 (formed by, for example, an inkjet method).

The EL layers 24 are formed, by a deposition method or an inkjet method, in a region (subpixel region) surrounded by partition walls 23c. In a case where the light-emitting element layer 5 is an organic light-emitting diode (OLED) layer, the EL layer 24 is made up of, for example, a hole injection layer, a hole transfer layer, a light emission layer, an electron transfer layer, and an electron injection layer which are disposed in order from the bottom.

The first electrodes (anodes) 22 are each made up of, for example, a layer of indium tin oxide (ITO) and a layer of an Ag-containing alloy. The first electrode 22 has light reflectivity. The second electrode (e.g., cathode) 25 is a common electrode, and can be made of a transparent metal such as indium tin oxide (ITO) or indium zincum oxide (IZO).

In a case where the light-emitting element layer 5 is an OLED layer, a driving electric current between the first electrodes 22 and the second electrode 25 causes a hole and an electron to recombine with each other in the EL layer 24. By a resultant exciton reaching a ground state, light is emitted.

The present invention is not limited to an example in which the light-emitting element layer 5 constitutes OLED elements. Alternatively, the light-emitting element layer 5 can constitute inorganic light-emitting diodes or quantum-dot light-emitting diodes.

The sealing layer 6 includes (i) a first inorganic sealing film 26 covering the banks 23 and the second electrode 25, (ii) an organic sealing film 27 covering the first inorganic sealing film 26, and (iii) a second inorganic sealing film 28 covering the organic sealing film 27.

The first inorganic sealing film 26 and the second inorganic sealing film 28 can each be configured by, for example, (i) a silicon oxide film formed by CVD, (ii) a silicon nitride film formed by CVD, (iii) a silicon oxynitride film formed by CVD, or (iv) a laminated film made up of these films. The organic sealing film 27 is a light-transmissive organic insulating film, and is thicker than each of the first inorganic sealing film 26 and the second inorganic sealing film 28. The organic sealing film 27 can be made of, for example, a photosensitive organic material, such as polyimide or acrylic, which can be used for coating. For example, the first inorganic sealing film 26 is coated, by inkjet coating, with ink containing such an organic material, and then the ink is cured by irradiation with an ultraviolet ray. The sealing layer 6 covers the light-emitting element layer 5 so as to prevent the light-emitting element layer 5 from being permeated with a foreign matter such as water or oxygen.

The functional films 39 each have, for example, an optical compensation function, a touch sensor function, and/or a protection function. The electronic circuit board is, for example, an IC chip or a flexible printed circuit board, any of which is provided on the plurality of terminals TM.

### Embodiment 1

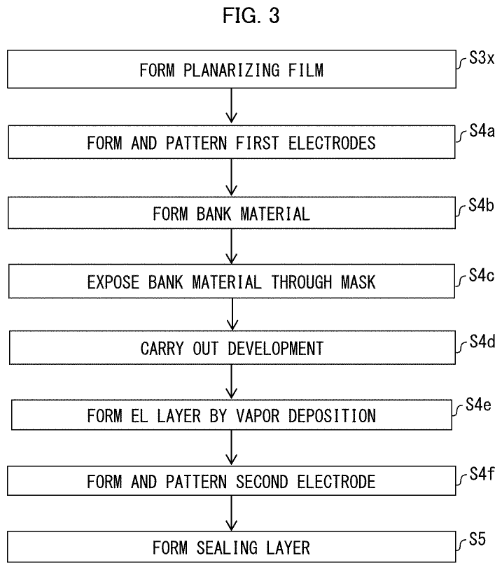

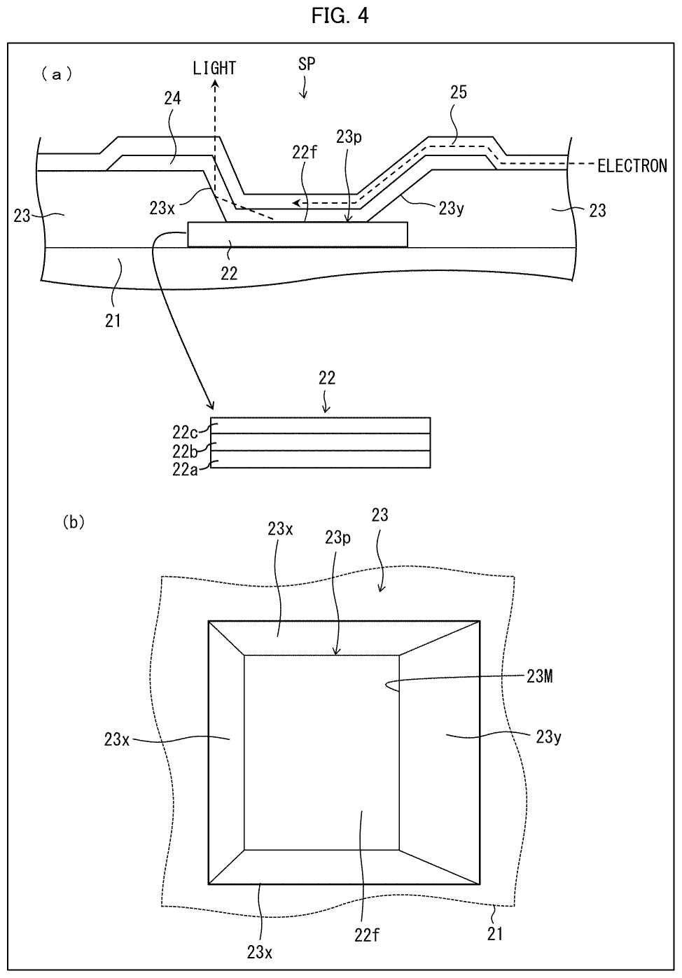

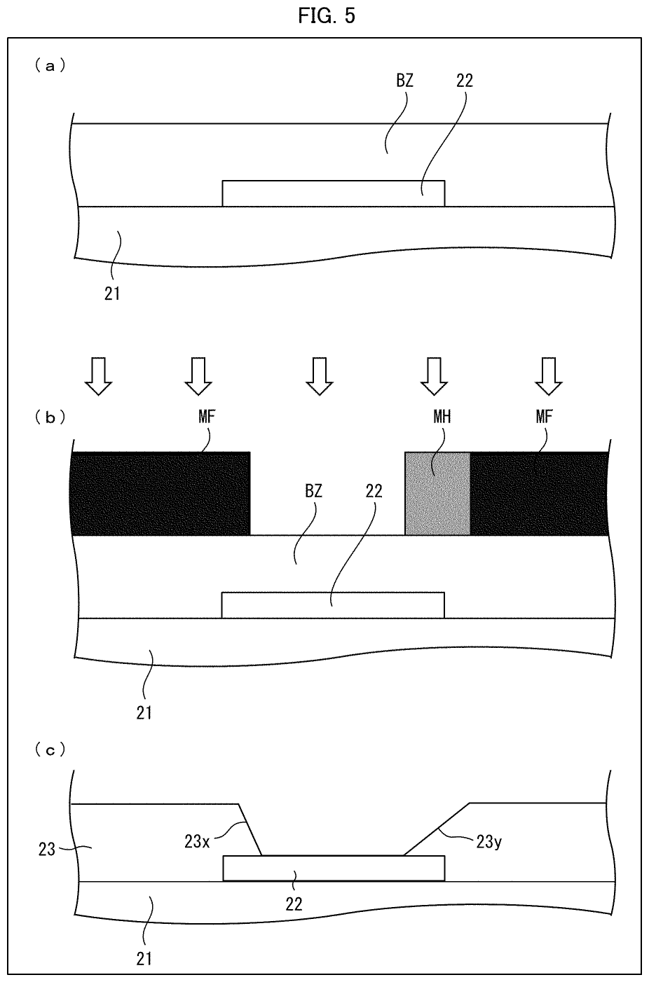

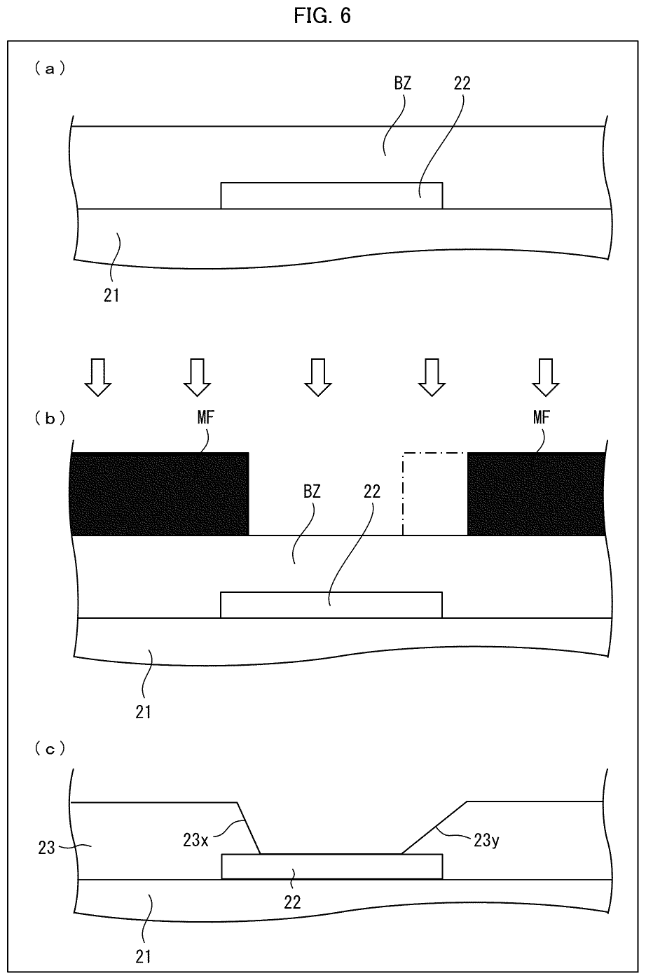

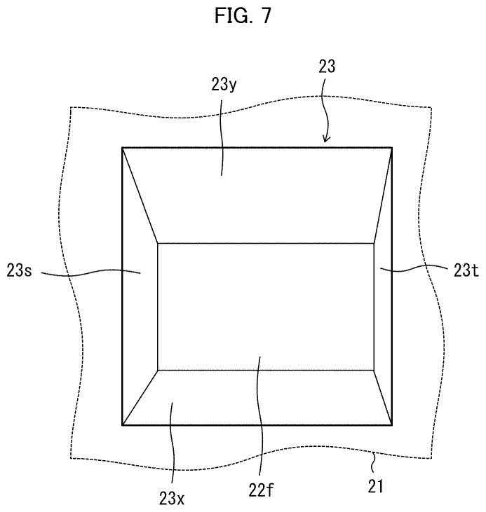

FIG. 3 is a flowchart illustrating steps involved in forming a light-emitting element layer. FIG. 4 is a set of views (a) and (b) which are a cross-sectional view and a plan view, respectively, illustrating a subpixel structure in accordance with Embodiment 1. FIG. 5 is a view schematically illustrating steps involved in formation of a bank in accordance with Embodiment 1. FIG. 6 is a view schematically showing a variation of steps involved in formation of the bank in accordance with Embodiment 1. FIG. 7 is a plan view illustrating a variation of the bank in accordance with Embodiment 1.

As illustrated in FIGS. 3 through 5, in Step S3 illustrated in FIG. 1, a planarizing film 21 serving as a foundation layer of an EL element is formed (Step S3x). Next, on the planarizing film 21, first electrodes 22 are formed and patterned (Step S4a). The first electrodes 22 are formed in the form of islands, and have light reflectivity. Specifically, each of the first electrodes 22 includes a base film 22a, a light reflective film 22b, and a light transmissive film 22c, each of which is electrically conducive. Note that the base film 22a and the light transmissive film 22c are each made of, for example, ITO.

Next, coating is carried out with a bank material BZ which is, for example, a photosensitive resin, so that a film is formed to cover the first electrodes 22 ((a) of FIG. 5, Step S4b). Examples of the photosensitive resin encompass polyimide, epoxy, and acrylic, each of which contains a photosensitive material. Next, masks MF and MH are provided on the bank material BZ, and the bank material BZ is exposed to light ((b) of FIG. 5, Step S4c). Note that the mask MF is a full mask (light blocking property of 1.0), and the mask MF is a gray tone mask (light blocking property of 0 to 1.0).

Next, the bank material BZ is immersed in a developer, so that parts of the bank material BZ, which parts were exposed to light, are removed according to the amount of exposure (Step S4d). This causes a first sloped part 23x and a second sloped part 23y, which has an inclination smaller than that of the first sloped part, to be formed at an inner side of the bank 23 covering edges of the first electrode 22 (see (c) of FIG. 5). An inclination angle of the first sloped part is less than 50° (preferably not more than 30°). An inclination angle of the second sloped part is not less than 50° (preferably not less than 60°). At a bottom surface 23p of the bank, an upper surface 22f of the first electrodes 22 is exposed. In (b) of FIG. 4, the bottom surface 23p of the bank 23 has a rectangular shape having four sides when viewed from above. In addition, when viewed from above, an intersection 23M of the second sloped part 23y and the bottom surface 23p corresponds to an entirety of one of the sides of the rectangular shape.

FIG. 5 shows that (i) the bank material BZ is a positive photosensitive resin and (ii) the second sloped part 23y is developed by providing the gray tone mask MH at a tapering shape forming part and then carrying out exposure. However, the present invention is not limited to such an example. For example, the second sloped part 23y can be formed by carrying out selective exposure without providing a mask at the tapering shape forming part (see FIG. 6).

Next, an EL layer 24 is formed by vapor deposition (Step S4e). In this example, the EL layer 24 is in contact with the upper surface 22f of the first electrodes 22. In addition, the EL layer 24 covers the first sloped part 23x and second sloped part 23y. The EL layer 24 and the bank 23 preferably have respective different refractive indexes. The refractive index of the bank 23 is more preferably smaller than that of the EL layer 24 (for example, the bank 23 and the EL layer 24 have refractive indexes of 1.6 and 1.7, respectively).

Next, a second electrode is formed and patterned (Step S4e). This allows an EL element, which includes the first electrode 22, the bank 23, the EL layer 24, and the second electrode 25, to be provided in each of a plurality of subpixels SP in the active region. Note that the second electrode is a so-called a solid electrode, and is shared by the plurality of subpixels.

According to the display device in accordance with Embodiment 1, the second sloped part 23y is provided so as to have a small inclination as illustrated in (a) of FIG. 4. This makes it unlikely for the second electrode 25 to suffer step-caused disconnection, so that conductivity of the second electrode 25 is guaranteed. Furthermore, light, which has been emitted in the EL layer 24 in the inner side of the bank 23, can be efficiently reflected upwards (toward the sealing layer) by the first sloped part 23x having a large inclination. This allows light extraction efficiency at the subpixels to be high.

Note that at the bank 23 covering the edges of the first electrode 22 in the form of an island, it is possible to provide (i) a fourth sloped part 23s having an inclination larger than that of the first sloped part 23x and (ii) a fourth sloped part 23t having an inclination larger than that of the third sloped part 23s (see FIG. 7).

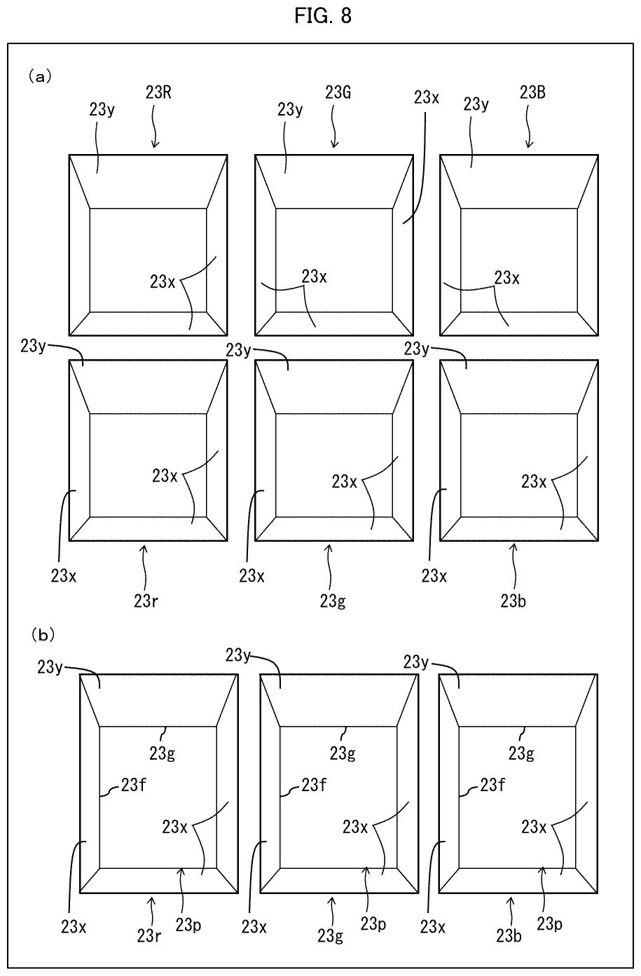

FIG. 8 is a plan view showing an example of an arrangement of a plurality of banks in accordance with Embodiment 1. In an example of (a) of FIG. 8, respective banks (e.g., 23R and 23G) of two subpixels having respective different colors and being adjacent to each other are arranged so that a first sloped part 23x of one bank and a first sloped part 23x of the other bank are adjacent to each other. In addition, respective banks (e.g., 23R and 23r) of two subpixels having identical colors and being adjacent to each other are arranged so that a first sloped part 23x of one bank and a second sloped part 23y of the other bank are adjacent to each other. With this configuration, a distance between subpixels having respective different colors can be reduced, so that it is possible to achieve high definition. As illustrated in (b) of FIG. 8, it is possible that a side 23f is longer than a side 23g, the side 23f being defined by an intersection of the bottom surface 23p of the bank and the first sloped part 23x, and the side 23g being defined by an intersection of the bottom surface 23p and the second sloped part 23y.

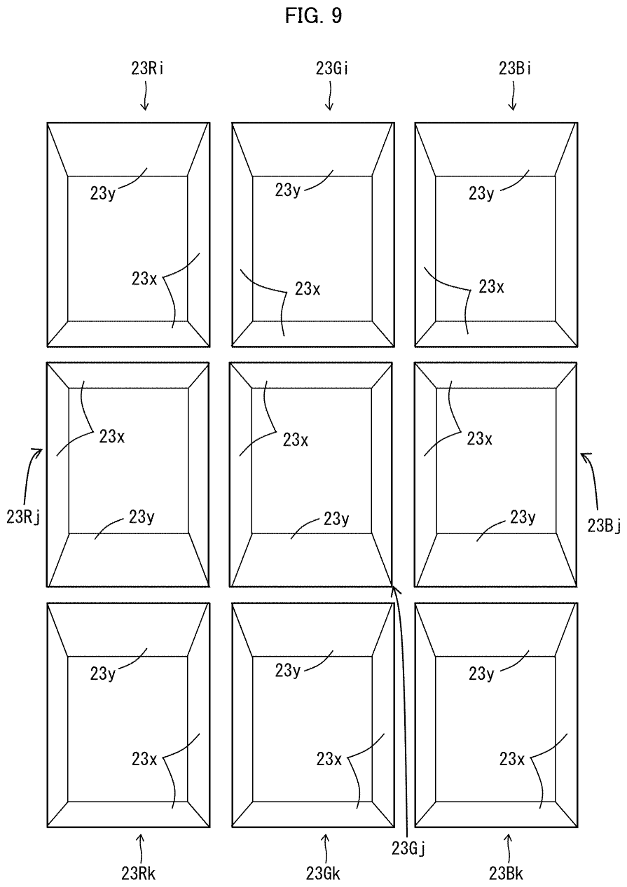

Alternatively, there can be a configuration illustrated in FIG. 9 which is different than the configuration illustrated in (a) of FIG. 8. Specifically, respective banks (e.g., 23Ri and 23Gi) of two subpixels having respective different colors and being adjacent to each other are arranged so that a first sloped part 23x of one bank and a first sloped part 23x of the other bank are adjacent to each other. In addition, respective banks (e.g., 23Ri and 23Rj) of two subpixels having identical colors and being adjacent to each other are arranged so that a first sloped part 23x of one bank and a first sloped part 23x of the other bank are adjacent to each other. Likewise, respective banks (e.g., 23Rj and 23Rk) of two subpixels having identical colors and being adjacent to each other are arranged so that a second sloped part 23y of one bank and a second sloped part 23y of the other bank are adjacent to each other.

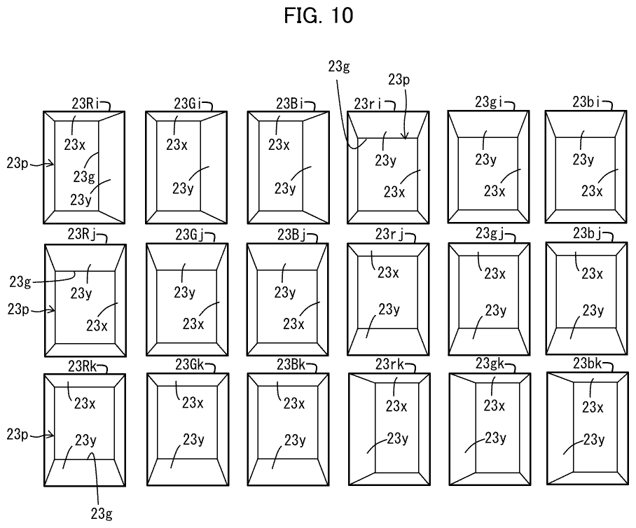

Alternatively, a configuration illustrated in FIG. 10 is also possible. Specifically, subpixels having identical colors are arranged in a column direction (vertically), and subpixels having respective red, green, and blue colors are arranged in a row direction (horizontally). For example, the banks 23Ri and 23Rj of two subpixels having identical colors and being adjacent to each other in the column direction are arranged so that an intersection 23g of a bottom surface 23p and a second sloped part 23y of the bank 23Ri of one subpixel and an intersection 23g of a bottom surface 23p and a second sloped part 23y of the bank 23Rj of the other subpixel extend in differing directions when viewed from center parts of the respective bottom surfaces 23p. In addition, for example, the banks 23Ri and 23ri of two subpixels having identical colors and being adjacent to each other in the row direction are arranged so that the intersection 23g of the bottom surface 23p and the second sloped part 23y of the bank 23Ri of one subpixel and an intersection 23g of a bottom surface 23p and a second sloped part 23y of the bank 23ri of the other subpixel extend in differing directions when viewed from center parts of the respective bottom surfaces 23p. In a case where the configuration illustrated in FIG. 10 is employed, changes in luminance and tint in the column direction and in the row direction are difficult to observe.

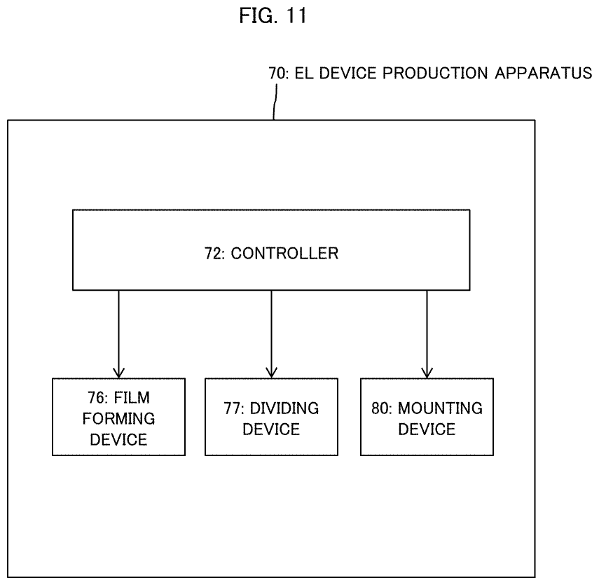

FIG. 11 is a block diagram illustrating a configuration of the display device production apparatus in accordance with Embodiment 1. As illustrated in FIG. 11, a display device production apparatus 70 includes (i) a film forming device 76, (ii) a dividing device 77, (iii) a mounting device 80, and (iv) a controller 72 for controlling these devices. In response to the control by the controller 72, the film forming device 76 carries out Steps S4a through S4f illustrated in FIG. 4.

### Embodiment 2

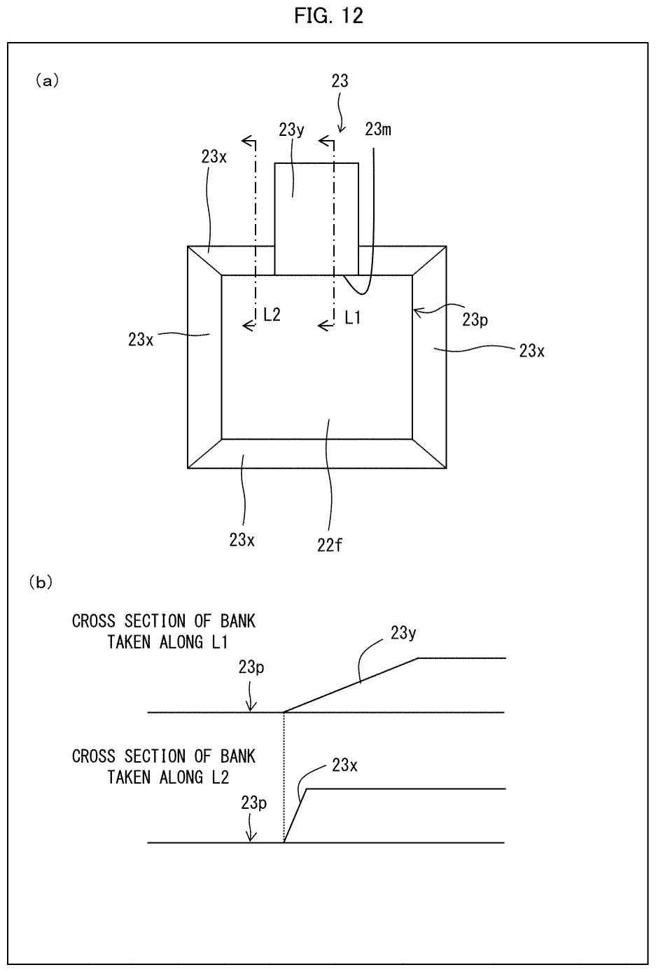

According to Embodiment 1, the intersection 23M of the second sloped part 23y and the bottom surface 23p of the bank corresponds, when viewed from above, to the entirety of one of the sides of the bottom surface 23p (see (b) of FIG. 4). However, the present invention is not limited to such an example. FIG. 12 is a set of views (a) and (b) which are a plan view and a cross-sectional view, respectively, showing an example of a configuration of a bank in accordance with Embodiment 2. As illustrated in FIG. 12, when viewed from above, an intersection 23M of a second sloped part 23y and a bottom surface 23p of a bank can correspond to a part side of the bottom surface 23p (rectangular shape). This increases an amount of a sloped part having a large inclination, and therefore allows light extraction efficiency at subpixels to be high.

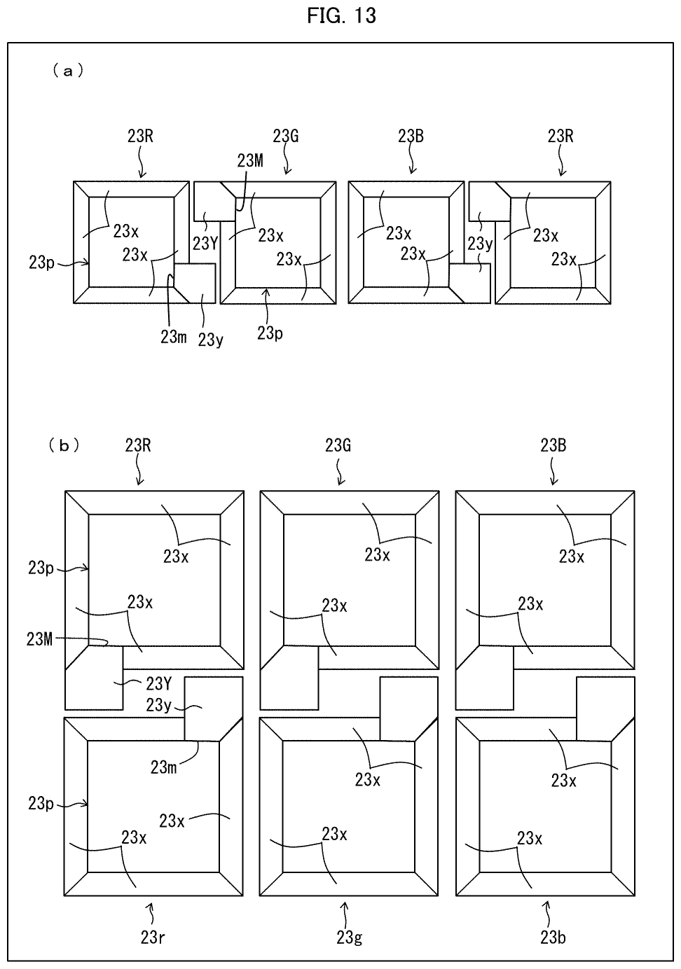

(a) of FIG. 13 is a plan view showing an example of an arrangement of a plurality of banks in accordance with Embodiment 2. As illustrated in (a) of FIG. 13, when viewed from above, second sloped parts 23y and 23Y extend in a row direction, from intersections 23m and 23M, respectively, of bottom surfaces 23p of the banks 23, where (i) the column direction is a direction (vertical direction in (a) of FIG. 13) in which banks of subpixels having identical colors are arranged and (ii) a row direction is a direction (horizontal direction in (a) of FIG. 13) in which banks of subpixels having respective different colors are arranged. Furthermore, when viewed from above, banks of subpixels having respective different colors and being adjacent to each other (e.g., 23R and 23G) are arranged so that (i) a side of one subpixel, which includes the intersection 23m, and a side of the other subpixel, which includes the intersection 23M, are adjacent to each other with a gap therebetween, which gap is located between the banks and (ii) the second sloped part 23y of one subpixel and the second sloped part 23Y of the other subpixel extend in opposite directions from respective positions which are different from each other in the column direction. According to the configuration illustrated in (a) of FIG. 13, (i) distances between subpixels having identical colors are equal in comparison with the case where no sloped parts having a small inclination are provided in banks and (ii) distances between subpixels having respective different colors are substantially equal in comparison with the case where no sloped parts having a small inclination are provided in banks. The configuration illustrated in (a) of FIG. 13 is therefore advantageous for achieving high definition.

(b) of FIG. 13 is a plan view showing an example of another arrangement of a plurality of banks in accordance with Embodiment 2. As illustrated in (b) of FIG. 13, when viewed from above, second sloped parts 23y and 23Y extend in the column direction, from intersections 23m and 23M, respectively, of bottom surfaces 23p of the banks 23. Furthermore, when viewed from above, banks of subpixels having identical colors and being adjacent to each other (e.g., 23R and 23r) are arranged so that (i) a side of one subpixel, which includes the intersection 23m, and a side of the other subpixel, which includes the intersection 23M, are adjacent to each other with a gap therebetween, which gap is located between the banks and (ii) the second sloped part 23y of one subpixel and the second sloped part 23Y of the other subpixel extend in opposite directions from respective positions which are different from each other in the row direction. According to the configuration illustrated in (b) of FIG. 13, (i) distances between subpixels having respective different colors are equal in comparison with the case where no sloped parts having a small inclination are provided in banks and (ii) distances between subpixels having identical colors are substantially equal in comparison with the case where no sloped parts having a small inclination are provided in banks. The configuration illustrated in (a) of FIG. 13 is therefore advantageous for achieving high definition.

### Embodiment 3

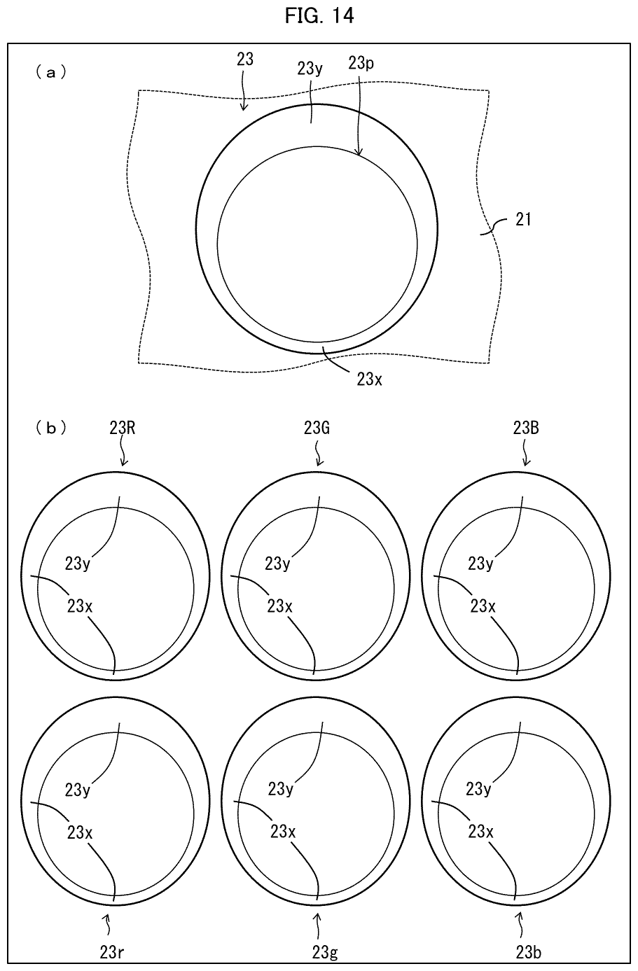

According to Embodiment 1, the bottom surface 23p of the bank 23 has a rectangular shape having four sides when viewed from above (see (b) of FIG. 4). However, the present invention is not limited to such an example. FIG. 14 is a plan view showing examples of (i) a configuration of a bank in accordance with Embodiment 3 and (ii) an arrangement of a plurality of banks in accordance with Embodiment 3. According to the example of FIG. 14, a bottom surface 23p of the bank has a circular shape or an elliptic shape when viewed from above. In an example of (b) of FIG. 14, respective banks (e.g., 23R and 23G) of two subpixels having respective different colors and being adjacent to each other are arranged so that a first sloped part 23x of one bank and a first sloped part 23x of the other bank are adjacent to each other. In addition, respective banks (e.g., 23R and 23r) of two subpixels having identical colors and being adjacent to each other are arranged so that a first sloped part 23x of one bank and a second sloped part 23y of the other bank are adjacent to each other. With this configuration, a distance between subpixels having respective different colors can be reduced, so that it is possible to achieve high definition.

An electro-optic element included in a display device in accordance with Embodiment 3 is not limited to any particular one. Examples of the display device encompass (i) an organic electro luminescence (EL) display including an organic light emitting diode (OLED) as an electro-optic element, (ii) an inorganic EL display including an inorganic light-emitting diode as an electro-optic element, and (iii) a QLED display including a quantum dot light emitting diode (QLED) as an electro-optic element.

Aspects of the present invention can also be expressed as follows:

A display device according to Aspect 1 includes: a plurality of subpixels: each of the plurality of subpixels including: a first electrode; a bank provided so as to cover an edge of the first electrode and; an EL layer provided in a layer higher than the first electrode; and a second electrode provided in a layer higher than the EL layer, the bank having a first sloped part and a second sloped part whose inclination is smaller than that of the first sloped part.

In Aspect 2, the first electrode has light reflectivity.

In Aspect 3, adjacent two subpixels, having respective different colors, are arranged so that (i) a first sloped part of one of the adjacent two subpixels and (ii) a first sloped part of the other of the adjacent two subpixels are adjacent to each other.

In Aspect 4, adjacent two subpixels, having identical colors, are arranged so that (i) a first sloped part of one of the adjacent two subpixels and (ii) a second sloped part of the other of the adjacent two subpixels are adjacent to each other.

In Aspect 5, the EL layer and the bank have respective different refractive indexes.

In Aspect 6, the refractive index of the bank is smaller than that of the EL layer.

In Aspect 7, the second electrode is shared by the plurality of subpixels.

In Aspect 8, the bank further has a third sloped part and a fourth sloped part so that (i) the third sloped part has an inclination larger than that of the first sloped part, and (ii)the fourth sloped part has an inclination larger than the third sloped part.

In Aspect 9, a first side is longer than a second side, the first side being defined by an intersection of a bottom surface of the bank and the first sloped part and the second side being defined by an intersection of the bottom surface of the bank and the second sloped part.

In Aspect 10, banks of respective adjacent two subpixels having identical colors are arranged so that an intersection of a bottom surface and a second sloped part of one of the banks and an intersection of a bottom surface and a second sloped part of the other of the banks extend in differing directions when viewed from center parts of the respective bottom surfaces.

In Aspect 11, a bottom surface of the bank has, when viewed from above, (i) a rectangular shape having four sides, (ii) a circular shape, or (iii) an elliptic shape.

In Aspect 12, an intersection of the second sloped part of the bank and a bottom surface of the bank corresponds to an entirety of one of the four sides of the rectangular shape when viewed from above.

In Aspect 13, an intersection of the second sloped part of the bank and a bottom surface of the bank corresponds to (matches) a part of one of the four sides of the rectangular shape when viewed from above.

In Aspect 14, when viewed from above, the second sloped part extends in a row direction from the intersection, where (i) a column direction is a direction in which subpixels having identical colors are arranged and (ii) the row direction is a direction in which subpixels having respective different colors are arranged.

In Aspect 15, when viewed from above, the second sloped part extends in a column direction from the intersection, where (i) the column direction is a direction in which subpixels having identical colors are arranged and (ii) a row direction is a direction in which subpixels having respective different colors are arranged.

In Aspect 16, when viewed from above, banks of respective adjacent two subpixels having identical colors are arranged so that (i) a side of one subpixel, which includes an intersection, and a side of the other subpixel, which includes an intersection, are adjacent to each other with a gap therebetween, which gap is located between the banks and (ii) a second sloped part of the one subpixel and a second sloped part of the other subpixel extend in opposite directions from respective positions which are different from each other in the row direction.

In Aspect 17, the EL layer is in contact with an upper surface of the first electrode.

In Aspect 18, the EL layer covers the first sloped part and the second sloped part.

In Aspect 19, the second sloped part has an inclination angle of not more than 30°.

In Aspect 20, the first sloped part has an inclination angle of not less than 50°.

In Aspect 21, the first electrode includes a base film, a light reflective film, and a light transmissive film, each of which is electrically conducive.

In Aspect 22, the base film and the light transmissive film are each made of ITO.

In Aspect 23, the first electrode, the EL layer, and the second electrode together constitute an OLED.

In Aspect 24, the first electrode is an anode of the OLED.

In Aspect 25, the bank is made of polyimide.

A display device production method in accordance with Aspect 26 is a method of producing a display device, the display device including: a first electrode; a bank provided so as to cover an edge of the first electrode; an EL layer provided in a layer higher than the first electrode; and a second electrode provided in a layer higher than the EL layer, the method including the step of: forming a first sloped part and a second sloped part in the bank so that the second sloped part has an inclination smaller than that of the first sloped part.

In Aspect 27, the second sloped part is formed by developing after restrictive exposure carried out with use of a gray tone mask.

In Aspect 28, the second sloped part is formed by developing after selective exposure.

A film forming device in accordance with Aspect 29 is a film forming device for use in production of a display device, the display device including: a first electrode; a bank provided so as to cover an edge of the first electrode; an EL layer provided in a layer higher than the first electrode; and a second electrode provided in a layer higher than the EL layer, the film forming device being configured to form a first sloped part and a second sloped part in the bank so that the second sloped part has an inclination smaller than that of the first sloped part.

A controller in accordance with Aspect 30 is a controller for controlling the film forming device to form a first sloped part and a second sloped part in the bank so that the second sloped part has an inclination smaller than that of the first sloped part.

Note that the present invention is not limited to the foregoing embodiments, and the present invention also encompasses, in its technical scope, any embodiment derived by combining technical means disclosed in differing embodiments. Further, it is possible to form a new technical feature by combining the technical means disclosed in the respective embodiments.

### Reference Signs List

2 Display device

4 TFT layer

5 Light-emitting element layer

6 Sealing layer

10 Base material

12 Resin layer

16 Inorganic insulating film

18 Inorganic insulating film

20 Inorganic insulating film

21 Interlayer insulating film

22 First electrode

23 Bank

23p Bottom surface of bank

23m, 23M Intersection

23x First sloped part

23y, 23Y Second sloped part

23i Third sloped part

23j Fourth sloped part

24 EL layer

25 Second electrode

26 First inorganic sealing film

27 Organic sealing film

28 Second inorganic sealing film

70 Display device production apparatus

76 Film forming device

SP Subpixel

1. A display device comprising a plurality of subpixels:
each of the plurality of subpixels including:
a first electrode;
a bank provided so as to cover an edge of the first electrode;
an EL layer provided in a layer higher than the first electrode; and
a second electrode provided in a layer higher than the EL layer,
the bank having a first sloped part and a second sloped part whose inclination is smaller than that of the first sloped part.

2. The display device as set forth in claim 1, wherein
the first electrode has light reflectivity.

3. The display device as set forth in claim 1, wherein
adjacent two subpixels, having respective different colors, are arranged so that (i) a first sloped part of one of the adjacent two subpixels and (ii) a first sloped part of the other of the adjacent two subpixels are adjacent to each other.

4. The display device as set forth in claim 1, wherein
adjacent two subpixels, having identical colors, are arranged so that (i) a first sloped part of one of the adjacent two subpixels and (ii) a second sloped part of the other of the adjacent two subpixels are adjacent to each other.

5. The display device as set forth in claim 1, wherein
the EL layer and the bank have respective different refractive indexes.

6. The display device as set forth in claim 5, wherein
the refractive index of the bank is smaller than that of the EL layer.

7. The display device as set forth in claim 1, wherein
the second electrode is shared by the plurality of subpixels.

8. The display device as set forth in claim 1, wherein
the bank further has a third sloped part and a fourth sloped part so that (i) the third sloped part has an inclination larger than that of the first sloped part, and (ii) the fourth sloped part has an inclination larger than the third sloped part.

9. The display device as set forth in claim 1, wherein
a first side is longer than a second side,
the first side being defined by an intersection of a bottom surface of the bank and the first sloped part and
the second side being defined by an intersection of the bottom surface of the bank and the second sloped part.

10. The display device as set forth in claim 1, wherein
banks of respective adjacent two subpixels having identical colors are arranged so that an intersection of a bottom surface and a second sloped part of one of the banks and an intersection of a bottom surface and a second sloped part of the other of the banks extend in differing directions when viewed from center parts of the respective bottom surfaces.

11. The display device as set forth in claim 1, wherein
a bottom surface of the bank has, when viewed from above, (i) a rectangular shape having four sides, (ii) a circular shape, or (iii) an elliptic shape.

12. The display device as set forth in claim 11, wherein
an intersection of the second sloped part of the bank and a bottom surface of the bank corresponds to an entirety of one of the four sides of the rectangular shape when viewed from above.

13. The display device as set forth in claim 11, wherein
an intersection of the second sloped part of the bank and a bottom surface of the bank corresponds to a part of one of the four sides of the rectangular shape when viewed from above.

14. The display device as set forth in claim 13, wherein
when viewed from above, the second sloped part extends in a row direction from the intersection, where (i) a column direction is a direction in which subpixels having identical colors are arranged and (ii) the row direction is a direction in which subpixels having respective different colors are arranged.

15. The display device as set forth in claim 13, wherein
when viewed from above, the second sloped part extends in a column direction from the intersection, where (i) the column direction is a direction in which subpixels having identical colors are arranged and (ii) a row direction is a direction in which subpixels having respective different colors are arranged.

16. The display device as set forth in claim 15, wherein
when viewed from above, banks of respective adjacent two subpixels having identical colors are arranged so that (i) a side of one subpixel, which includes an intersection, and a side of the other subpixel, which includes an intersection, are adjacent to each other with a gap therebetween, which gap is located between the banks and (ii) a second sloped part of the one subpixel and a second sloped part of the other subpixel extend in opposite directions from respective positions which are different from each other in the row direction.

17. The display device as set forth in claim 1, wherein
the EL layer is in contact with an upper surface of the first electrode.

18. The display device as set forth in claim 1, wherein
the EL layer covers the first sloped part and the second sloped part.

19. The display device as set forth in claim 1, wherein
the second sloped part has an inclination angle of not more than 30°.

20. The display device as set forth in claim 1, wherein
the first sloped part has an inclination angle of not less than 50°.

21-30. (canceled)
